(19) United States
(12) Patent Application Publication
(10) Pub. No.: US 2003/0057973 A1
(43) Pub. Date: Mar. 27, 2003

(54) Smart-tool and method of generating haptic sensation thereof

(76) Inventors: Takuya Nojima, Musashino-shi (JP); Dairoku Sekiguchi, Meguro-ku (JP); Masahiko Inami, Katsushika-ku (JP); Kunihiko Mabuchi, Itabashi-ku (JP); Susumu Tachi, Tsukuba-shi (JP)

Correspondence Address: OLIFF & BERRIDGE, PLC, P.O. BOX 19928, ALEXANDRIA, VA, 22320, US

(21) Appl. No.: 10/213,087

(22) Filed: Aug. 7, 2002

(30) Foreign Application Priority Data
Aug. 8, 2001 (JP) 2001-240127

(51) Int. Cl. G01R 23/17; G01R 31/308

(52) U.S. Cl. 324/753

(57) ABSTRACT

The present invention provides a smart tool for real-time measurement of a changing environment and real-time display of such information to the user, thereby supporting the user for example in surgery. Visual information in the vicinity of the tool tip is displayed to the user of the tool as haptic information. The smart tool comprises a tool (surgical knife), a light-receiving element for receiving the light reflected by an object in the vicinity of the tool tip, a decision portion for deciding the brightness and/or color of the object in the vicinity of the tool tip based on the output from said light-receiving element, a repulsive force calculation portion for calculating the repulsive force to be applied to said tool based on the output from said decision portion, a motor driving circuit for applying repulsive force to said tool based on the output from the repulsive force calculation portion, a motor, and a wire.

The present application claims priority of Japanese patent application No. 2001-240127 filed Aug. 8, 2001, the disclosure of which is fully incorporated by reference herein.

### BACKGROUND OF THE INVENTION

1. Field of the Invention

The present invention relates to a smart tool wherein a sensor, a tool and an information display device are integrated into one device, which realizes haptization of information by displaying non-haptic information as haptic information, and the method of generating haptic sensation of the smart tool.

2. Description of the Related Art

Technologies related to haptic (meaning “sense of force”; hereinafter the same) display are being frequently used in the general society, and many researches are being conducted relating to the application of such technologies. Such researches are presently still directed at realizing the display of haptic sensation that is close to real sensation, namely, which can be hardly distinguished from the sense of touching an object in reality. This type of display may be necessary for simulations in the medical field or for games in the amusement field. However, due to the complexity of haptic sensations, there is still no all-purpose haptic display that closely presents haptic sensations of the real world. Therefore, application of haptic display technologies in the general society should not be directed at perfectly displaying haptic sensations but at integrating with reality.

The following points can be said from the viewpoint of the origin of haptic displays and virtual reality:

1. Haptic sensation is “impedance information” relating to an object when touching the object, and the method of displaying such information is a “haptic display;”

2. “Virtual reality” is the “essence of reality,” and “information” essential to a certain purpose must be displayed to the user; and

3. “Augmented reality” is different from “reality,” but is the same in that it displays necessary “information” to the user. However, such information is commonly too much inclined toward visual information.

Conventional haptic displays present haptic information by setting appropriate impedance to a virtual object. “Information” conveyed by the impedance is information related to the “impedance of the object being touched.” The flow of conventional “haptic reality” strives to completely reproduce this information. However, in the present invention, necessary information other than the impedance of the object is conveyed by the impedance information. Thereby, augmented reality using haptic sensation can be realized. “Touchable information” is realized, i.e., non-haptic information is presented through haptic sensation.

This, namely the augmented haptics on information, will be described below. According to conventional methods, a sensor attached to (or in the surrounding of) a tool is used to obtain information on the environment of the tool; the obtained information is displayed visually or acoustically to the user, who then performs processing of the information in his mind. However, in the present invention, information is displayed haptically (impedance information).

A currently found example, the fire alarm cover, shows this clearly. This type of cover basically functions to prevent operational mistakes, but also displays, with maximum impedance, information meaning “Do not press this button except in situation of fire”. This method can reduce the burden of information processing on the user, and the number of mistakes caused thereby. Information meaning “Do not press” is displayed through impedance.

In the example described above, impedance is displayed using an actual object, but in the medical field, it should be possible to display information relating to dangerous areas that should not be touched during surgical operation through impedance. Dangerous tools used for surgery such as knives and needles are moved by the doctor's hand so as not to injure organs in the patient's body that are relevant to the patient's life, but actually, the above-mentioned dangerous area changes dynamically. This dynamically changing dangerous area is measured in real time, and information meaning “Do not touch” is displayed in real time through impedance. Thereby, the course of information processing normally starting from visual recognition, judgment of dangerous area within the brain, and control of the body so as not to touch the area can be commissioned to an external device.

In this case, it should be noted that in all cases, the user should take initiative in acting. It is not an object of the present invention to control the operation of the user exactly in the way the system designer has simulated it, but merely to provide “information” through “impedance,” and to reduce the burden of information processing on the user. This objective is not restricted to the medical field.

Factors essential to the realization of the present invention are: a) function as a normal tool; b) mechanism of real time measurement; and c) mechanism of real time display. A tool having all of these three functions is necessary, and this tool will be called herein a “smart tool.” By using this smart tool, the flow of information that conventionally passed through the mind of the user forms a loop via the environment, the tool, and the hand of the user, thereby allowing reduction of the burden on the user. In other words, the “tool” “knows” the information and passes on the information to the user through a method unique to the tool.

### SUMMARY OF THE INVENTION

The present invention was made from the above-described perspectives, and aims at providing a smart tool wherein a sensor, a tool and an information display device are integrated into one device, and information is presented to the user in the form of impedance.

The smart tool is a new type of Augmented Reality (AR) The smart tool is made of real-time sensing devices and a haptic display. The sensor senses real environments that change dynamically, and displays that information to the user through haptic sensation. In other words, the smart tool makes it possible to “touch” the dynamic information of real environment in real time.

An object of the present invention is to provide a smart tool that measures a dynamically changing environment in real time for example in a surgical operation, and displays the information in real time to the user so as to support the user.

Another object of the present invention is to provide a smart tool that can “touch” the interface between two different liquids, for example.

The present invention is a smart tool for displaying non-haptic information relating to the environment of a tool as haptic information to the user of said tool, comprising: said tool; a sensor for detecting the environment surrounding said tool; an environmental information measurement portion for gaining environmental information on said tool based on the output from said sensor; an environmental information/haptic sensation conversion portion for converting the gained environmental information to haptic sensation; and a haptic display for conveying the converted haptic sensation to said tool.

The present invention is a smart tool for displaying visual information in the vicinity of the tip of a tool as haptic information to the user of said tool, comprising: said tool; a light-receiving element for receiving the light reflected by an object in the vicinity of the tip of said tool; a decision portion for deciding the brightness and/or color of the object in the vicinity of the tip of said tool based on the output from said light-receiving element; a repulsive force calculation portion for calculating the repulsive force to be applied to said tool based on the output from said decision portion; and a haptic display for applying repulsive force to said tool based on the output from said repulsive force calculation portion.

The present invention is a smart tool for displaying information on the interface between liquids in the surrounding of a tool as haptic information to the user of said tool, comprising: said tool; a first electrode attached to the tip of said tool; a second electrode placed within a liquid; an ammeter for measuring the value of the electric current flowing through said first electrode and said second electrode; a decision portion for deciding the electric resistance based on the electric current value measured by said ammeter; a repulsive force calculation portion for calculating the repulsive force based on the gained electric resistance; and a haptic display for applying repulsive force to said tool based on the output from said repulsive force calculation portion.

The present invention is a smart tool for displaying information on the interface between liquids in the surrounding of a tool as haptic information to the user of said tool, comprising: said tool; a first electrode and a second electrode attached to the tip of said tool; an ammeter for measuring the value of the electric current flowing through said first electrode and said second electrode; a decision portion for deciding the electric resistance based on the electric current value measured by said ammeter; a repulsive force calculation portion for calculating the repulsive force based on the gained electric resistance; and a haptic display for applying repulsive force to said tool based on the output from said repulsive force calculation portion.

The present invention is a smart tool for displaying information on the surface of a distant object as haptic information to the user of a tool, comprising: a range finder for measuring the distance to said object; a distance change detection portion for detecting changes in said distance; a conversion portion for converting changes in the detected distance to haptic sensation; and a haptic display for applying haptic sensation based on the output from said conversion portion.

The present invention is a smart tool for displaying information on the surface of a distant object as haptic information to the user of a tool, comprising: a light-receiving portion for receiving the light reflected by the surface of said object; a detection portion for detecting the state of said surface based on the intensity of the light received by said light-receiving portion; a conversion portion for converting the detected surface state to haptic sensation; and a haptic display for applying haptic sensation based on the output from said conversion portion.

The present invention is a smart tool for displaying information on a distant object as haptic information to the user of a tool, comprising: a proximity sensor for detecting information relating to an object existing in the vicinity; a conversion portion for converting information on the detected object to haptic sensation; and a haptic display for applying haptic sensation based on the output from said conversion portion.

The present invention is a haptic sensation generation method of a smart tool, comprising the steps of: an operator operating said tool; measuring the environment in the surrounding of said tool and gaining environmental information other than haptic sensation; calculating the haptic sensation to be applied to said tool based on said environmental information; and applying the calculated haptic sensation to said tool.

### BRIEF DESCRIPTION OF THE DRAWINGS

FIG. 1 shows the structure of the smart tool according to Embodiment 1;

FIG. 2 is a flow chart of the operation of Embodiment 1;

FIG. 3 is a view explaining the operation of Embodiment 1;

FIG. 4 shows the structure of the smart tool according to Embodiment 2;

FIG. 5 is a view explaining the operation of Embodiment 2;

FIG. 6 shows the structure of the smart tool according to Embodiment 3;

FIG. 7 shows the structure of the smart tool according to a variation of Embodiment 3; and

FIG. 8 shows the structure of the smart tool according to Embodiment 4.

### DESCRIPTION OF THE PREFERRED EMBODIMENTS

Embodiment 1.

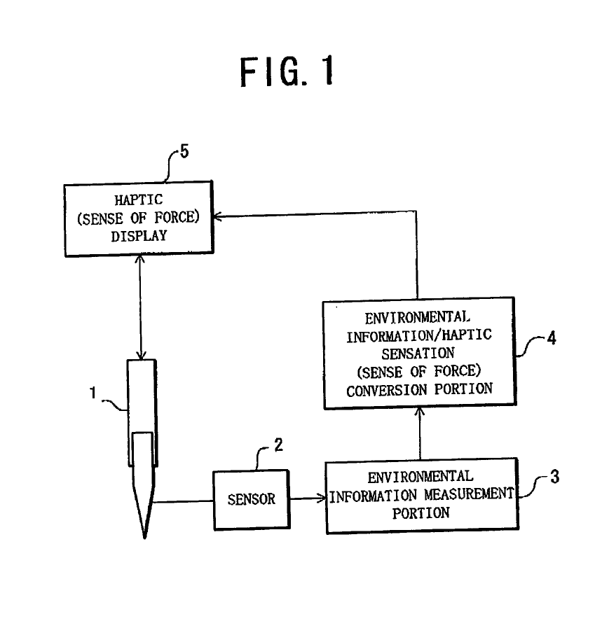

FIG. 1 shows the concept of the smart tool according to an embodiment of the present invention.

In FIG. 1, numeral 1 denotes a tool operated by the user, 2 denotes a sensor for detecting the environment of the tool (especially the tool tip), 3 denotes an environmental information measurement portion for gaining information on the environment of tool 1 based on the output from sensor 2, 4 denotes an environmental information—haptic sensation (sense of force) conversion portion for converting the gained environmental information to haptic sensation (sense of force), and 5 denotes a haptic (sense of force) display for conveying haptic sensation (sense of force) to tool 1.

Sensor 2 is attached in the vicinity of the portion of tool 1 that is to operate on the object. For example, if tool 1 is in the form of a rod with the tip touching the object, sensor 2 is provided on the rod tip. Information gained by sensor 2 is non-haptic information. In other words, the smart tool according to the present invention gives feedback to the tool user regarding non-haptic information in the form of haptic sensation. Haptic sensation means information that the user senses with his sense of touch. The sense of touch presented by the smart tool includes a repulsive force working against the force of the user operating the tool, a vibration of the tool itself, a heat generation of the tool itself, an electric current (electric shock), and a sense of the tool itself bending (a repulsive force and a force crossing the direction of the force applied by the user).

Conventionally, users also used the feeling from the tool, namely the sense of force, similarly to the visual and auditory senses as a source of information. The smart tool aims at providing a sensor on a tool that is used for a specific operation and at thereby actively displaying information gained from the sensor to the user in the form of information relating to the sense of force.

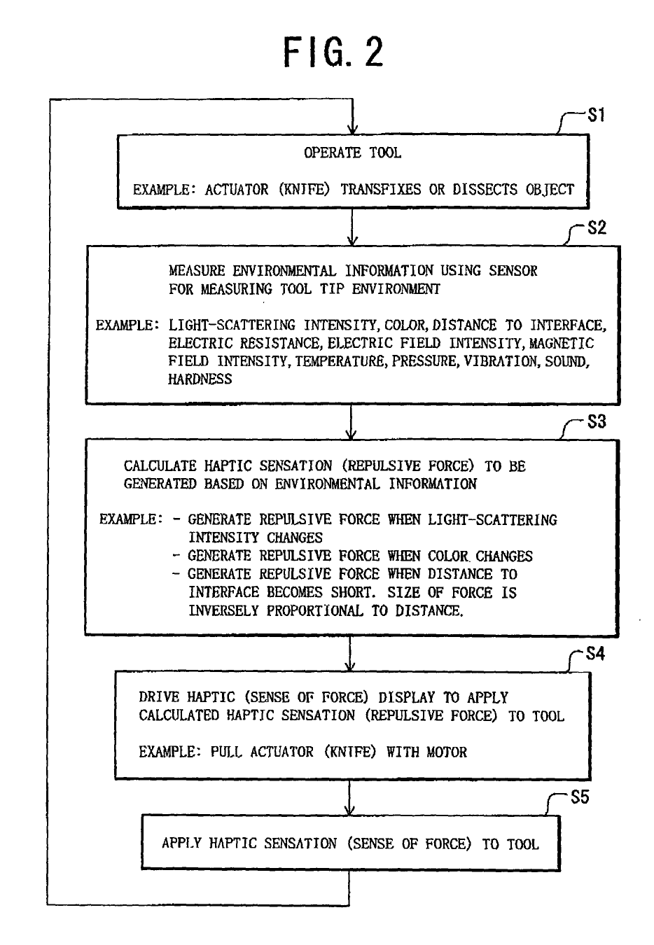

Now, the operation of Embodiment 1 will be explained with reference to FIG. 2.

S1: The operator operates tool 1. If tool 1 is a surgical knife, the operator transfixes or dissects the object with tool 1.

S2: A sensor 2 for measuring the environment of the tip of tool 1 is used to measure the environmental information. Examples of sensor 2 and the environmental information measured therewith are shown below:

optical sensor (light-emitting diode combined with photodetector): light-scattering intensity, color, distance to interface

electrical sensor (ammeter, voltmeter): electric resistance, electric field intensity

magnetic field sensor: magnetic field intensity

temperature sensor (thermocouple): temperature

pressure sensor: pressure, vibration, sound, hardness

S3: Based on the environmental information, the haptic sensation (repulsive force) to be applied to tool 1 is calculated, for example as below:

Repulsive force is generated when the light-scattering intensity changes.

Repulsive force is generated when the color changes.

Repulsive force is generated when the distance to the interface becomes short. The size of the force is inversely proportional to the distance.

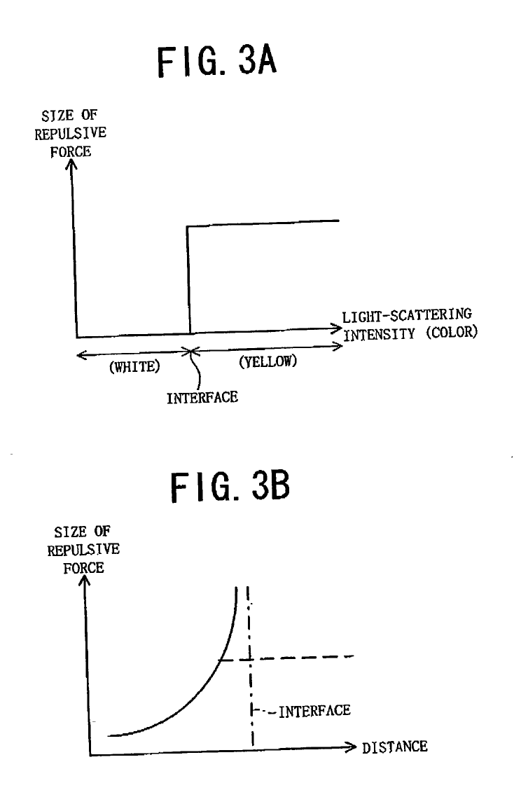

As shown in FIG. 3 (a), when the output from sensor 1 (or a parameter calculated based on this output) exceeds a predetermined threshold value, a certain size of repulsive force may be generated. The portion of the threshold value corresponds for example to the interface. It is also possible to cause the generated repulsive force to increase when the output from sensor 1 nears the predetermined threshold value. For example, a repulsive force that is inversely proportional to the distance to the interface is generated. As shown in FIG. 3(b) by dotted lines, it is also possible to set a maximum limit to the size of the repulsive force.

S4: Haptic (sense of force) display 5 is driven so as to apply the calculated haptic sensation (repulsive force) to tool 1.

For example, by pulling the actuator (knife) with a motor, repulsive force working against the force of the user operating the tool is applied. By rotating a weight with the motor, vibration can be applied to the tool itself. By energizing a heater within the tool, the tool itself can generate heat. It is possible to apply a weak electric current to the tool. It is also possible to apply a repulsive force and a force crossing the direction of the force applied by the user to the tool to generate a haptic sensation as if the tool itself were bending.

S5: Haptic sensation (sense of force) is applied to the tool.

The smart tool is characterized in that a sensor, a tool and an actuator are integrated in one device, and direct feedback on the information of the tool is given to the tool via the sensor and actuator.

The smart tool has the following advantages:

1) The existing skills of the operator can be used almost fully in their current state because the same or similar tools as the operator usually uses can be used.

2) By providing a real-time environment measurement sensor on the tool, the tool can be used in a dynamically changing actual environment.

3) By providing the tool on a sense of force display, instinctive display of information using sense of force is possible.

4) Environmental information in the surrounding of the tool is collected and sense of force is displayed through the tool itself, so the environmental position of the collected information is consistent with the position of the tool to be controlled, which is easy to understand. If the positions were not consistent, coordinate conversion processing to make the coordinates of the environment and tool consistent would be necessary.

Embodiment 2.

Embodiment 2 of the present invention is a smart tool directed at real time surgery support. The tool used in this smart tool is a knife. When dissecting the human body using this smart tool, important tissue within the body such as the artery is set in advance as a dangerous area; the positional relationship between such tissue and the tool tip is measured in real time; and the measured information is presented to the operator through sense of force.

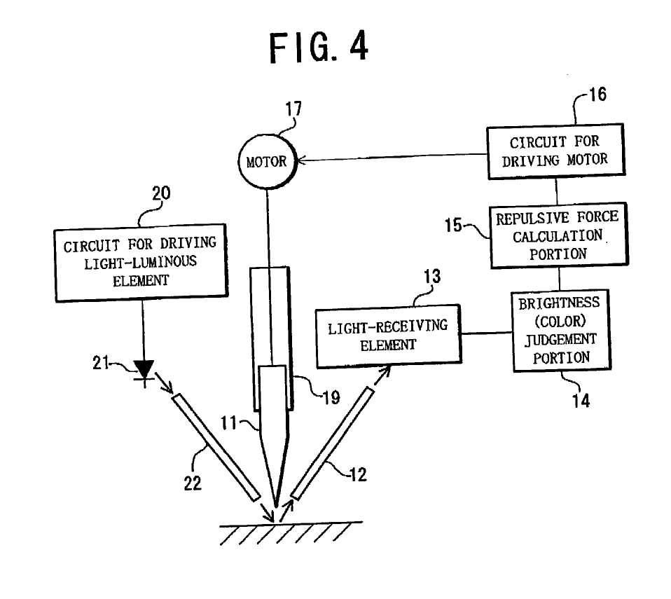

FIG. 4 shows a smart tool according to Embodiment 2 of the present invention.

11 denotes the tool which is a knife; 12 denotes an optical fiber that guides the light reflected by the object (human body) in the vicinity of the tip of knife 11 to a light-receiving element 13; 14 denotes a brightness (color) decision portion for deciding the brightness or color of the object in the vicinity of the tip of knife 11 based on the light guided by optical fiber 12; 15 denotes a repulsive force calculation portion for calculating the repulsive force to be applied to knife 11 based on the output from said brightness (color) decision portion 14; 16 denotes a motor driving circuit for driving a motor 17 based on the output from repulsive force calculation portion 15; 17 denotes a motor for applying repulsive force to knife 11 by pulling a wire 18; 18 denotes the wire for conveying the driving force of motor 17 to knife 11; 19 denotes a case for housing knife 11; 20 denotes a circuit for driving the light-receiving element; 21 denotes a light-emitting element such as a light-emitting diode; and 22 denotes an optical fiber for guiding the light from the light-emitting element to the vicinity of the tip of knife 11. The smart tool of the present invention is structured to only generate repulsive force away from a structurally set dangerous area. The smart tool operates as shown in FIGS. 2 and 3. For example, when the tip of knife 11 is about to harm an important organ, motor 17 generates a braking force in the form of impedance information to inform the user of a dangerous area and at the same time stops knife 11 so as not to harm the important organ.

Sensors 12, 13, 21 and 22 are required to: 1. work in real time; and 2. take up as little space as possible (as they are to be incorporated in the tool). In Embodiment 2, these sensors are not required to be highly precise or have high resolution.

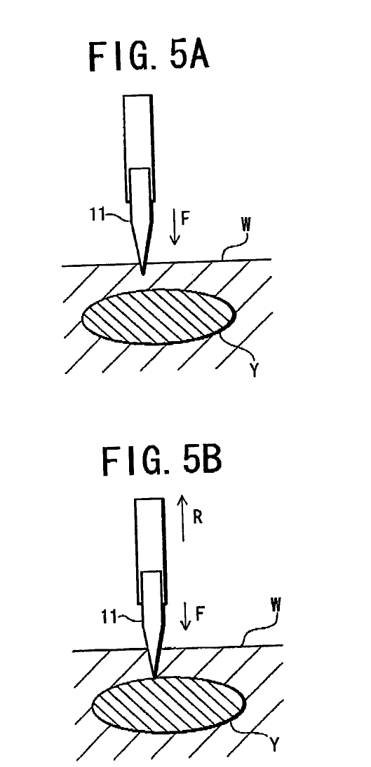

Now, a detailed operation of the smart tool will be described with reference to FIG. 5. In this case, a boiled egg is used instead of the human body as the object, using the egg as an example of the human body, where the egg yolk is set as a dangerous area denoting important tissue in the human body. In FIG. 5, W denotes the egg white and Y denotes the egg yolk.

A force F is applied to the smart tool to cause knife 11 to intrude into the inside of the egg (FIG. 5(a)). When knife 11 intrudes further, the actuator (made of a motor 17 and a wire 18) applies a braking force immediately before egg yolk Y (R in FIG. 5 (b)). Accordingly, knife 11 does not intrude into egg yolk Y but stops immediately before the yolk. To be more accurate, the operator of knife 11 is informed that the tip of the knife has reached the area where intrusion is prohibited, and stops the intrusion.

As in the case in FIG. 5(a), when the operator moves the tool in an area sufficiently far away from the predetermined dangerous area Y, the sense of force display generates no load. However, as in the case in FIG. 5(b), when real time sensor 13 provided on tool 1 senses that the tool has neared the predetermined dangerous area Y, it generates a load via sense of force displays 17 and 18 according to predetermined conditions, and displays to the user the distance relationship to the dangerous area via sense of force, which is an intuitive means of displaying information to the user. If repulsive force working away from the dangerous area is used as the generated load, not only information display is gained but there is also the advantageous practical effect of reducing the possibility of harming important tissue by the tool intruding into the dangerous area.

The smart tool displays to the user via impedance that the tool tip has reached the dangerous area, so important organs are not harmed by the knife tip.

The smart tool can also be applied to cases where a needle or scissor is used as the tool instead of knife 11.

Embodiment 2 of the smart tool as described above calculates linear information such as the distance between the tool and a predetermined area, and, based thereon, performs linear control on the tool. It is also possible to perform further control by pre-setting the optimal track, speed and/or size of force according to which the tool should move, calculating the difference between the actual track, speed and/or size of force of the tool and the optimal setting, and displaying haptic sensation (sense of force) to the tool based on the calculated difference.

The above variation only generates the track, speed and size of force that are “optimal” based on a purely physical model, and displays information based thereon to the user.

Embodiment 3.

The smart tool according to Embodiment 3 is used as an interface for “touching” the interface between two liquids. Usually, nobody could feel the interface between two liquids, because they are liquids. However, using this tool, based on the smart tool technology, the sensor on the tool senses the interface between two liquids and displays that information through haptic sensation to the user. The user could write something on the interface between two liquids using this tool.

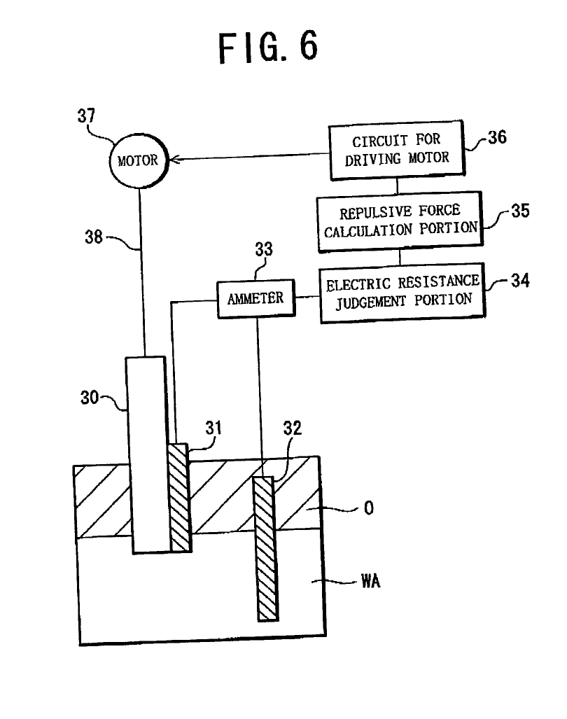

FIG. 6 shows the structure of the smart tool.

30 denotes a rod for intruding into water WA and oil O and informing the user of the interface; 31 denotes an electrode provided on the tip of rod 30; 32 denotes an electrode placed within water WA; 33 denotes an ammeter for measuring the value of the electric current flowing between electrodes 31 and 32; 34 denotes a decision portion for deciding the electric resistance based on the electric current value; 35 denotes a repulsive force calculation portion for calculating the repulsive force based on the electric resistance; 36 denotes a motor driving circuit for driving motor 37 based on the output from repulsive force calculation portion 35; and 37 denotes a motor for applying repulsive force to rod 30 via wire 38.

The smart tool performs the operation as described for Embodiments 1 and 2.

In the device shown in FIG. 6, a user (not illustrated) holds tool 30 in his hand. When the user moves the tool from the oil layer to the water layer, electric current flows between electrodes 31 and 32, which is decided by ammeter 33 and electric resistance decision portion 34, and, based on the decision results, the repulsive force is calculated and motor 37 applies the repulsive force to rod 30. Accordingly, the user can feel a solid interface between water WA and oil O.

Furthermore, it is shown that the user can draw pictures on the interface. At first, the sensor on the tool detects the interface between oil and water containing phenolphthalein. The sensor has an electrode, which can cause electrolysis. If the user moves the tool with very weak force, the tool would not go through the interface and the user could not write anything. However, if the user moves the tool with slightly stronger force, the electrode goes through to the water layer and causes electrolysis. The electrolysis changes the acidity so that the phenolphthalein changes its color to red.

It is described above that the smart tool can “touch” the interface. The smart tool can change the hardness of the interface between the oil layer and the water layer. However, just by changing the control algorithm of the system, it is possible not only to change the hardness of the environment, but also the viscosity or any other physical parameter.

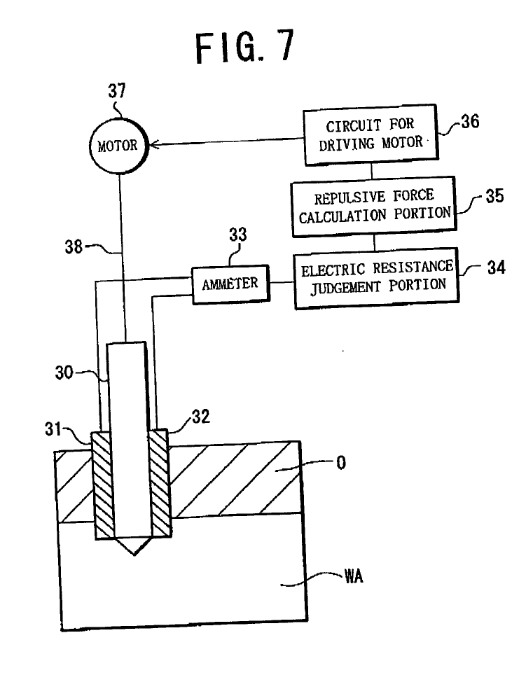

In Embodiment 3 described above, one electrode 32 was put into the liquid, and the other electrode 31 was attached to tool 30. It is also possible to attach both electrodes 31, 32 to tool 30, as shown in FIG. 7.

Through the structure as shown in FIG. 7, the intrusion length of electrodes 31, 32 into the liquid shows a relatively smooth proportional relationship with the resistance value between electrodes 31, 32, which is advantageous in measuring the intrusion length into the liquid with the sensor.

The resistance value between the two electrodes 31 and 32 inside the liquid depends upon the length of the electrode inside the liquid and the distance between the electrodes. The resistance value is approximated by rough inverse proportion to the length of the electrodes inside the liquid and rough proportion to the distance, for example. Therefore, in the case in FIG. 6, the resistance changes not only according to the intrusion volume of electrodes 31 and 32 into the liquid but also according to the distance between electrodes 31 and 32, so it is relatively difficult to decide the volume of the electrodes into the liquid from the sensor value. However, in the case in FIG. 7, it is possible to hold the distance between electrodes 31, 32 constant. Therefore, there is only one factor that has an effect on the sensor output, thereby enabling relative accurate measurement of the resistance value depending only on the intrusion volume.

Embodiment 4.

The smart tool according to Embodiment 4 of the present invention is used as an interface for knowing the state of the surface of a distant object.

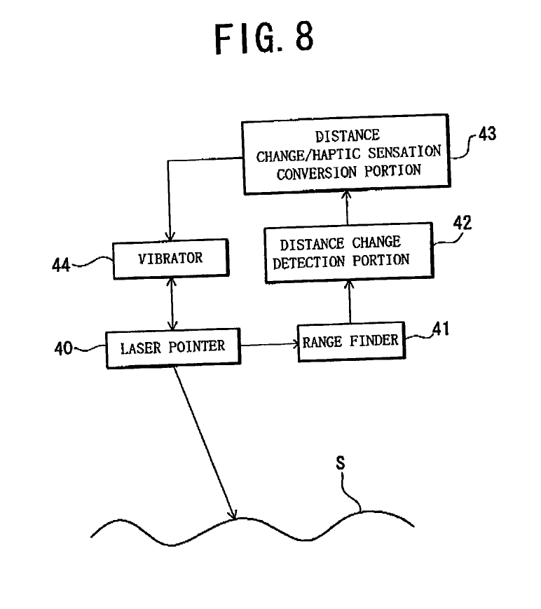

FIG. 8 shows the structure of the smart tool.

40 denotes a laser pointer for radiating a narrow laser beam onto the surface of a distant object; 41 denotes a range finder for measuring the distance to the portion radiated by the laser beam; 42 denotes a distance change detection portion for detecting any distance change; 43 denotes a distance change/haptic sensation conversion portion for converting a distance change to haptic sensation; and 44 denotes a vibrator (voice coil) for causing laser pointer 40 to vibrate. Range finder 41 measures the distance from laser pointer 40 to the light spot of the laser beam. Distance measurement is performed for example by measuring the time until the laser beam is reflected and comes back.

In the smart tool, when the user holds laser pointer 40 and moves it to a certain object, the distance to the object changes. When this distance change becomes a predetermined value or more, distance change/haptic sensation conversion portion 43 generates a drive signal for vibrator 44. Then, laser pointer 40 vibrates and conveys a sensation to the user as if he were touching the surface with a rod.

Furthermore, it is also possible to measure the surface state (roughness) using light-scattering intensity instead of the distance change and generate haptic sensation based thereon.

Another alternative is to use a proximity sensor instead of range finder 41, and apply vibration to the tool when an obstacle or the like nears the vicinity of the tool. An example of a proximity sensor is one that radiates radio waves or ultrasonic waves and receives the reflected waves.

Furthermore, laser pointer 40 is not an essential element, and it may be omitted.

The embodiment of the present invention may be applied to tools for supporting blind people, for example. By incorporating the smart tool into the walking stick, the user can know uneven places on the road such as stairs and steps through vibration of the stick. By providing a range finder and/or proximity sensor on both ends of the stick, it is also possible to inform the user not only of the surface of the street but also of obstacles at higher positions.

As an alternative to vibrator 44, it is possible to use a pin array type display that can display uneven places through haptic sensation. A pin array type display is covered with many pins, and shapes are realized through haptic sensation by moving the pins one by one up and down. In this case, an actuator is used to move the pins. When moving these many pins with a small device, a device used for Braille display can be used.

When a proximity sensor can be used to know the shape of uneven places on the road, the shape can be conveyed to the user through this pin array type display.

Instead of vibrator 44, it is also possible to use an inertial actuator. This actuator is provided with at least one weight, and the weight is moved abruptly according to the direction of the uneven place, thereby informing the user of the uneven place through the change in movement.

In this type of actuator, the weight is normally in standstill, and when displaying an uneven place, the weight is moved abruptly. If the weight is moved in the inside of a rod-shaped tool, the weight can be moved forward and backward, so two directional types of stimuli are possible. As an alternative, it is possible to display two impact directions by actually hitting the weight against the tip of the tool and the end of the tool.

The present invention is not limited to the above embodiments; variations are possible within the scope of the claims, which are incorporated in the scope of the present invention.

The component elements referred to herein do not always mean physical means but include cases where the functions of each means are realized through software. Furthermore, the functions of one means may be realized through two or more physical means, or the functions of two or more means may be realized through one physical means.

What is claimed is:

1. A smart tool for displaying non-haptic information relating to the environment of a tool as haptic information to the user of said tool, comprising:
said tool;
a sensor for detecting the environment surrounding said tool;
an environmental information measurement portion for gaining environmental information on said tool based on the output from said sensor;
an environmental information/haptic sensation conversion portion for converting the gained environmental information to haptic sensation; and
a haptic display for conveying the converted haptic sensation to said tool.

2. A smart tool according to claim 1, wherein said sensor is one of an optical sensor, an electrical sensor, a magnetic field sensor, a temperature sensor, and a pressure sensor; said environmental information is one of light-scattering intensity, color, distance to interface, electric resistance, electric field intensity, magnetic field intensity, temperature, pressure, vibration, sound, and hardness; and said haptic sensation is information sensed by the human being through sense of touch, and is one of a repulsive force working against the force of the person operating the tool, a vibration of the tool itself, heat generation of the tool, and an electric shock using electric current.

3. A smart tool according to claim 1, wherein said sensor is an optical sensor, said environmental information measurement portion measures the light-scattering intensity based on the output from said optical sensor, and said environmental information/haptic sensation conversion portion converts changes in said light-scattering intensity to repulsive force.

4. A smart tool according to claim 1, wherein said sensor is an optical sensor, said environmental information measurement portion decides the color based on the output from said optical sensor, and said environmental information/haptic sensation conversion portion converts changes in said color to repulsive force.

5. A smart tool according to claim 1, wherein said sensor is a distance sensor, said environmental information measurement portion measures the distance to an interface based on the output from said distance sensor, and said environmental information/haptic sensation conversion portion converts changes in said distance to the interface to repulsive force.

6. A smart tool according to claim 1, wherein said sensor is an ammeter, said environmental information measurement portion measures the electric resistance of the environment based on the output from said ammeter, and said environmental information/haptic sensation conversion portion converts changes in said electric resistance to repulsive force.

7. A smart tool according to claim 1, wherein said sensor is a sensor for measuring the surface state of an object including the roughness thereof, said environmental information measurement portion measures the surface state of the object based on the output from said sensor, and said environmental information/haptic sensation conversion portion converts changes in said surface state to vibration.

8. A smart tool according to claim 1, wherein said sensor is a proximity sensor, said environmental information measurement portion detects an object in the vicinity of said tool based on the output from said proximity sensor, and said environmental information/haptic sensation conversion portion converts information on the existence of said object to vibration.

9. A smart tool according to claim 1, wherein said haptic display is an actuator for pulling said tool.

10. A smart tool according to claim 1, wherein said haptic display is a heater for heating said tool.

11. A smart tool according to claim 1, wherein said haptic display is a source of current for applying an electric shock to the person holding said tool.

12. A smart tool according to claim 1, wherein said haptic display is a vibrator for applying vibration to said tool.

13. A smart tool according to claim 1, wherein said haptic display is a pin array type display for displaying uneven places through sense of touch.

14. A smart tool according to claim 1, wherein said haptic display is an inertial actuator that comprises at least one weight and that displays changes in the movement of said weight through haptic sensation.

15. A smart tool according to claim 14, wherein said actuator applies a force crossing the direction of the force applied by a person to the tool, and applies a haptic sensation to the person as if the tool itself were bending.

16. A smart tool according to claim 1, further comprising:
a storage portion for pre-storing the optimal track along which said tool should move, the speed and/or size of the force applied to said tool;
a measurement portion for measuring the track of said tool, the speed and/or size of the force applied to said tool; and
a processing portion for comparing the measurement result of said measurement portion with the storage contents of said storage portion, calculating the difference between them, and converting the calculated difference to haptic sensation.

17. A smart tool for displaying visual information in the vicinity of the tip of a tool as haptic information to the user of said tool, comprising:
said tool;
a light-receiving element for receiving the light reflected by an object in the vicinity of the tip of said tool;
a decision portion for deciding the brightness and/or color of the object in the vicinity of the tip of said tool based on the output from said light-receiving element;
a repulsive force calculation portion for calculating the repulsive force to be applied to said tool based on the output from said decision portion; and
a haptic display for applying repulsive force to said tool based on the output from said repulsive force calculation portion.

18. A smart tool for displaying information on the interface between liquids in the surrounding of a tool as haptic information to the user of said tool, comprising:
said tool;
a first electrode attached to the tip of said tool;
a second electrode placed within a liquid;
an ammeter for measuring the value of the electric current flowing through said first electrode and said second electrode;
a decision portion for deciding the electric resistance based on the electric current value measured by said ammeter;
a repulsive force calculation portion for calculating the repulsive force based on the gained electric resistance; and
a haptic display for applying repulsive force to said tool based on the output from said repulsive force calculation portion.

19. A smart tool for displaying information on the interface between liquids in the surrounding of a tool as haptic information to the user of said tool, comprising:
said tool;
a first electrode and a second electrode attached to the tip of said tool;
an ammeter for measuring the value of the electric current flowing through said first electrode and said second electrode;
a decision portion for deciding the electric resistance based on the electric current value measured by said ammeter;
a repulsive force calculation portion for calculating the repulsive force based on the gained electric resistance; and
a haptic display for applying repulsive force to said tool based on the output from said repulsive force calculation portion.

20. A smart tool for displaying information on the surface of a distant object as haptic information to the user of a tool, comprising:
a range finder for measuring the distance to said object;
a distance change detection portion for detecting changes in said distance;
a conversion portion for converting changes in the detected distance to haptic sensation; and
a haptic display for applying haptic sensation based on the output from said conversion portion.

21. A smart tool for displaying information on the surface of a distant object as haptic information to the user of a tool, comprising:
a light-receiving portion for receiving the light reflected by the surface of said object;
a detection portion for detecting the state of said surface based on the intensity of the light received by said light-receiving portion;
a conversion portion for converting the detected surface state to haptic sensation; and
a haptic display for applying haptic sensation based on the output from said conversion portion.

22. A smart tool for displaying information on a distant object as haptic information to the user of a tool, comprising:
a proximity sensor for detecting information relating to an object existing in the vicinity;
a conversion portion for converting information on the detected object to haptic sensation; and
a haptic display for applying haptic sensation based on the output from said conversion portion.

23. A haptic sensation generation method of a smart tool, comprising the steps of:
an operator operating said tool;
measuring the environment in the surrounding of said tool and gaining environmental information other than haptic sensation;
calculating the haptic sensation to be applied to said tool based on said environmental information; and
applying the calculated haptic sensation to said tool.
